(19) United States
(12) Patent Application Publication
(10) Pub. No.: US 2021/0351102 A1
(43) Pub. Date: Nov. 11, 2021

(54) HEAT RADIATION MATERIAL, METHOD FOR PRODUCING A HEAT RADIATION MATERIAL, COMPOSITION, AND HEAT-GENERATING ELEMENT

(71) Applicant: Showa Denko Materials Co., Ltd., Tokyo (JP)

(72) Inventors: Maki ITO, Tokyo (JP); Takashi ANDOU, Tokyo (JP); Yoshitaka TAKEZAWA, Tokyo (JP)

(73) Assignee: Showa Denko Materials Co., Ltd., Tokyo (JP)

(21) Appl. No.: 17/281,994

(22) PCT Filed: Oct. 4, 2018
(86) PCT No.: PCT/JP2018/037247

§ 371 Date: Apr. 1, 2021

(51) Int. Cl. H01L 23/373; C09K 5/14; C08K 3/08

(52) U.S. Cl. CPC H01L 23/3737; C08K 2003/085; C08K 3/08; C09K 5/14

(57) ABSTRACT

This heat radiation material contains metal particles and a resin, and has a structure in which the metal particles are localized in at least one surface side.

### TECHNICAL FIELD

The present invention relates to a heat radiation material, a heat radiation material production method, a composition, and a heat-generating element.

### BACKGROUND ART

In recent years, the size reduction and multifunctionalization of electronic devices have created a tendency for the amount of heat generated per unit area to increase. As a result, a heat spot, at which heat locally concentrates in an electronic device, is generated and problems of the malfunction of electronic devices, the shortening of service lives, the degradation of operation stability, the degradation of reliability, and the like are caused. Therefore, the importance of mitigating the generation of a heat spot by radiating heat generated from a heat-generating element to the outside is growing.

A heat radiation measure in practice for electronic devices is to install a heat dissipater such as a metal plate or a heat sink in the vicinity of a heat-generating element in an electronic device, conduct heat generated from the heat-generating element to the heat dissipater, and dissipate the heat to the outside. As means for fixing a heat dissipater to an electronic device, a thermally conductive pressure-sensitive sheet (heat radiation material) is used. For example, Patent Literature 1 describes a heat radiation material with metal particles inserted into a resin sheet in order to efficiently transfer heat generated from a heat-generating component to a heat dissipater.

### REFERENCE LIST

### Patent Literature

Patent Literature 1: Japanese Patent Laid-Open No. 2000-129215

### SUMMARY

### Technical Problem

The heat radiation material described in Patent Literature 1 is made to be highly thermally conductive by inserting the metal particles into the resin sheet, but the heat radiation range is limited to the inside of the sheet, and thus there is a room for improvement from the viewpoint of improvement in the heat radiation property.

In consideration of the above-described circumstances, an objective of an aspect of the present invention is to provide a heat radiation material capable of efficient radiation heat transfer of heat generated from a heat-generating element and a production method of the same. An object of another aspect of the present invention is to provide a composition for forming this heat radiation material and a heat-generating element including this heat radiation material.

### Solution to Problem

Means for solving the above-described problem include the following embodiments.

<1> A heat radiation material containing metal particles and a resin and having a structure in which the metal particles are localized in at least one surface side.

<2> The heat radiation material according to <1>, in which a region in which the metal particles are present at a relatively high density is present in the at least one surface side.

<3> The heat radiation material according to <2>, in which the region is present in a surface side that faces a heat-generating element.

<4> The heat radiation material according to <2> or <3>, in which the region is present in a surface side opposite to a surface that faces the heat-generating element.

<5> The heat radiation material according to any one of <2> to <4>, in which a thickness of the region is within a range of 0.1 μm to 100 μm.

<6> The heat radiation material according to any one of <2> to <5>, in which a proportion of a thickness of the region in a thickness of the entire heat radiation material is within a range of 0.02% to 99%.

<7> A heat radiation material containing metal particles and a resin, in which the metal particles include metal particles arrayed along a surface direction.

<8> A heat radiation material containing metal particles and a resin, in which a layer having an uneven structure derived from the metal particles on a surface is provided.

<9> A heat radiation material containing metal particles and a resin, in which a region 1 and a region 2 that satisfy (A) and (B) are provided.

(A) an absorptance of electromagnetic wave at wavelength of 2 μm to 6 μm in the region 1>an absorptance of electromagnetic wave at wavelength of 2 μm to 6 μm in the region 2

(B) a metal particle occupancy rate in the region 1>a metal particle occupancy rate in the region 2

<10> A heat radiation material production method including a step of forming a layer of a composition containing metal particles and a resin and a step of settling the metal particles in the layer.

<11> A heat radiation material production method including a step of disposing metal particles on a flat surface and a step of forming a resin layer on the metal particles.

<12> A heat radiation material production method including a step of preparing a resin layer and a step of disposing metal particles on the resin layer.

<13> A composition containing metal particles and a resin and used to produce the heat radiation material according to any one of <1> to <9>.

<14> A heat-generating element including the heat radiation material according to any one of <1> to <9>.

### Advantageous Effects of Invention

According to an aspect of the present invention, provided are a heat radiation material capable of efficient radiation heat transfer of heat generated from a heat-generating element and a production method of the same. According to another aspect of the present invention, provided are a composition for forming this heat radiation material and a heat-generating element including this heat radiation material.

### BRIEF DESCRIPTION OF THE DRAWINGS

FIG. 1 is a cross-sectional schematic view of a sample produced in Example 1.

FIG. 2 is an absorption wavelength spectrum of the sample produced in Example 1.

FIG. 3 is a cross-sectional schematic view of a sample produced in Example 2.

FIG. 4 is an absorption wavelength spectrum of the sample produced in Example 2.

FIG. 5 is a cross-sectional schematic view of a sample produced in Example 3.

FIG. 6 is an absorption wavelength spectrum of the sample produced in Example 3.

FIG. 7 is a cross-sectional schematic view of a sample produced in Example 4.

FIG. 8 is an absorption wavelength spectrum of the sample produced in Comparative Example 1.

FIG. 9 is an absorption wavelength spectrum of the sample produced in Comparative Example 2.

FIG. 10 is a cross-sectional schematic view of a sample produced in Comparative Example 3.

FIG. 11 is a cross-sectional schematic view of an electronic device produced in Example 7.

FIG. 12 is a cross-sectional schematic view of an electronic device produced in Example 8.

FIG. 13 is a cross-sectional schematic view of a heat pipe produced in Example 9.

### DESCRIPTION OF THE EMBODIMENTS

Hereinafter, embodiments for carrying out the present invention will be described in detail. However, the present invention is not limited to the following embodiments. In the following embodiments, configuration elements (also including element steps and the like) are not essential unless particularly clearly specified. This is also true for numerical values and ranges thereof, and configuration elements, numerical values, and ranges thereof do not limit the present invention.

The term “step” in the present disclosure refers not only to a step independent from other steps but also a step that cannot be clearly differentiated from other steps as long as the step achieves the intended purpose.

Numerical ranges expressed using “to” in the present disclosure include numerical values before and after “to” as the minimum value and the maximum value, respectively.

In numerical ranges expressed stepwise in the present disclosure, the upper limit value or the lower limit value described in one numerical range may be substituted into the upper limit value or the lower limit value of a different numerical range expressed stepwise. In addition, in a numerical range expressed in the present disclosure, the upper limit value or the lower limit value of the numerical range may be substituted into a value described in an example.

Each component in the present disclosure may contain a plurality of kinds of corresponding substances. In a case where there is a plurality of kinds of substances corresponding to each component in a composition, unless particularly otherwise described, the content rate or content of each component refers to the total content rate or content of the plurality of kinds of substances present in the composition.

As particles corresponding to each component in the present disclosure, a plurality of kinds of particles may be contained. In a case where there is a plurality of kinds of particles corresponding to each component in a composition, unless particularly otherwise described, the particle diameter of each component refers to a value regarding the mixture of the plurality of kinds of particles present in the composition.

At the time of observing a region in which a certain layer is present, the term “layer” in the present disclosure refers not only to a layer that is formed throughout the entire region but also to a layer that is formed only in a part of the region.

In the case of describing an embodiment with reference to a drawing in the present disclosure, the configuration of the embodiment is not limited to the configuration shown in the drawing. In addition, the size of a member in each drawing is a conceptual size, and the relative relationship between members in terms of the size is not limited to that in the drawing.

### Heat Radiation Material (First Embodiment)

A heat radiation material of the present embodiment is a heat radiation material that contains metal particles and a resin and has a structure in which the metal particles are localized in at least one surface side.

The heat radiation material having the above-described configuration exhibits an excellent heat radiating effect in the case of being installed in a heat-generating element. The reason therefor is not clear but is considered as described below.

Since the metal particles that are contained in the heat radiation material have a structure in which the metal particles are localized in at least one surface side, a region in which the metal particles are present at a relatively high density (hereinafter, also referred to as the metal particle layer) is formed in at least one surface side. The metal particle layer has a fine uneven structure attributed to the shapes of the metal particles on the surface. When heat is transferred to the metal particle layer from a heat-generating element, it is considered that surface plasmon resonance occurs and the wavelength range of electromagnetic waves that are radiated changes. As a result, it is considered that, for example, the emissivity of electromagnetic waves in a wavelength range in which the resin that is contained in the radiation material does not absorb electromagnetic waves relatively increases, the accumulation of heat by the resin is suppressed, and the heat radiation property improves.

In the heat radiation material of the present embodiment, the metal particle layer is formed in at least one surface side, thereby causing surface plasmon resonance. Therefore, it is possible to cause surface plasmon resonance by a simple method compared with, for example, methods in which the surface of a metal plate is processed to form a fine uneven structure, thereby causing surface plasmon resonance.

The form of the metal particle layer is not particularly limited as long as the metal particle layer is in a state of being capable of causing surface plasmon resonance. For example, a clear boundary may or may not be formed between the metal particle layer and a different region. In addition, the metal particle layer may be present continuously or discontinuously (or in a pattern shape) in the heat radiation material. The metal particles that are contained in the metal particle layer may or may not be in contact with adjacent particles.

The thickness (the thickness of a portion at which the thickness is minimized in a case where the thickness is not constant) of the metal particle layer is not particularly limited. The thickness may be, for example, within a range of 0.1 μm to 100 μm. The thickness of the metal particle layer can be adjusted using, for example, the amount of the metal particles that are contained in the metal particle layer, the sizes of the metal particles, or the like.

The proportion of the metal particle layer in the entire heat radiation material is not particularly limited. For example, the proportion of the thickness of the metal particle layer in the thickness of the entire heat radiation material may be within a range of 0.02% to 99%.

The density of the metal particles in the metal particle layer is not particularly limited as long as the metal particles are in a state of being capable of causing surface plasmon resonance. For example, at the time of observing the metal particle layer from the front surface, the area-based proportion of the metal particles in the observation surface is preferably 8% or more, more preferably 50% or more, still more preferably 75% or more, and particularly preferably 90%.

The proportion can be calculated using, for example, image processing software from an electron microscope image.

The position of the metal particle layer in the heat radiation material is not particularly limited as long as the position is in at least one surface side of the heat radiation material. For example, the metal particle layer may or may not be positioned on the outermost surface of at least one surface of the heat radiation material. In addition, the metal particle layer may be positioned on a surface side on which the heat radiation material faces a heat-generating element or may be positioned on a surface side opposite to the surface on which the heat radiation material faces the heat-generating element.

“The metal particle” in the present disclosure refer to a particle in which at least a part of the surface is metal, and the inside of the particle may or may not be metal. The inside of the particle is preferably metal from the viewpoint of improving the heat radiation property by thermal conduction.

In a case where at least a part of the surface of the metal particle is metal, a case where a substance other than metal such as a resin or a metal oxide is present in the vicinity of the metal particle is also regarded as the metal particle as long as an electromagnetic wave from the outside is capable of reaching the surface of the metal particle.

Examples of the metal that is contained in the metal particle include copper, aluminum, nickel, iron, silver, gold, tin, titanium, chromium, palladium, and the like. Only one kind of metal or two or more kinds of metal may be contained in the metal particle. In addition, the metal may be in a pure metal state or an alloy state.

The shape of the metal particle is not particularly limited as long as the metal particle is capable of forming a desired uneven structure on the surface of the metal particle layer. Specific examples of the shape of the metal particle include a spherical shape, a flake shape, a needle shape, a cuboid, a cube, a tetrahedron, a hexahedron, a polyhedron, a tubular shape, a hollow body, a three-dimensional needle-shaped structure extending in four different axial directions from the core part, and the like. Among these, a spherical shape or a shape similar to a spherical shape is preferable.

The size of the metal particle is not particularly limited. For example, the volume-average particle diameter of the metal particles is preferably within a range of 0.1 μm to 30 μm. When the volume-average particle diameter of the metal particles is 30 μm or less, there is a tendency that infrared light that contributes to heat radiation is sufficiently radiated. When the volume-average particle diameter of the metal particles is 30 μm or less, there is a tendency that electromagnetic waves that contribute to improvement in the heat radiation property (infrared light of relatively low wavelengths) is sufficiently radiated. When the volume-average particle diameter of the metal particles is 0.1 μm or more, there is a tendency that the cohesive force of the metal particles is suppressed and the metal particles are likely to be evenly arrayed.

The volume-average particle diameter of the metal particles may be set in consideration of the kind of a material other than the metal particles that is used in the heat radiation material. For example, as the volume-average particle diameter of the metal particles becomes smaller, the cycle of the uneven structure that is formed on the surface of the metal particle layer becomes shorter, and the wavelength at which the surface plasmon resonance that occurs in the metal particle layer is maximized becomes shorter. The absorptance of electromagnetic waves by the metal particle layer is maximized at the wavelength at which the surface plasmon resonance is maximized. Therefore, when the wavelength at which the surface plasmon resonance that occurs in the metal particle layer is maximized becomes short, the wavelength at which the absorptance of electromagnetic waves by the metal particle layer is maximized becomes short, and, according to the Kirchhoff s law, there is a tendency that the emissivity of electromagnetic waves at the wavelength increases. Therefore, when the volume-average particle diameter of the metal particles is appropriately selected, it is possible to change the radiation wavelength of the metal particle layer to a wavelength range in which the resin that is contained in the heat radiation material is less likely to absorb electromagnetic waves, and there is a tendency that the heat radiation property further improves.

The volume-average particle diameter of the metal particles that are contained in the metal particle layer may be 10 μm or less, may be 5 μm or less, and may be 3 μm or less. When the volume-average particle diameter of the metal particles is within the above-described range, it is possible to change the wavelength range of electromagnetic waves that are radiated to a low wavelength range in which the resin is less likely to absorb electromagnetic waves (for example, 6 μm or less). Therefore, it is possible to suppress the accumulation of heat by the resin and to further improve the heat radiation property.

The volume-average particle diameter of the metal particles in the present disclosure refers to the particle diameter (D50) that is a particle diameter when integration from the small diameter side reaches 50% in a volume-based particle size distribution curve that is obtained by the laser diffraction and scattering method.

From the viewpoint of effectively controlling the absorption or radiation wavelengths of electromagnetic waves by the metal particle layer, the variation in the particle diameters of the metal particles that are contained in the metal particle layer is preferably small. When the variation in the particle diameters of the metal particles is suppressed, it becomes easy to form a cyclic uneven structure on the surface of the metal particle layer, and there is a tendency that surface plasmon resonance is likely to occur.

Regarding the variation in the particle diameters of the metal particles, for example, when the particle diameter (D10) at which integration from the small diameter side reaches 10% in the volume-based particle size distribution curve is represented by A (μm) and the particle diameter (D90) at which integration from the small diameter side reaches 90% is represented by B (μm), the value of A/B preferably becomes approximately 0.3 or more, more preferably becomes approximately 0.4 or more, and still more preferably becomes approximately 0.6 or more.

The kind of the resin that is contained in the heat radiation material is not particularly limited, and the resin can be appropriately selected from well-known thermosetting resins, thermoplastic resins, ultraviolet-curable resins, and the like. Specific examples thereof include phenolic resins, alkyd resins, amino alkyd resins, urea resins, silicone resins, melamine urea resins, epoxy resins, polyurethane resins, unsaturated polyester resins, vinyl acetate resins, acrylic resins, rubber chloride-based resins, vinyl chloride resins, fluororesins, and the like. Among these, acrylic resins, unsaturated polyester resins, epoxy resins, and the like are preferable from the viewpoint of the heat resistance, the procuring property, or the like. Only one kind of resin or two or more kinds of resins may be contained in the metal particle layer.

The heat radiation material may also contain materials other than the resin and the metal particles. For example, the heat radiation material may contain ceramic particles, an additive, or the like.

When the heat radiation material contains ceramic particles, it is possible to further enhance the heat radiating effect of the heat radiation material. Specific examples of the ceramic particles include the particles of boron nitride, aluminum nitride, aluminum oxide, magnesium oxide, titanium oxide, zirconia, iron oxide, copper oxide, nickel oxide, cobalt oxide, lithium oxide, silicon dioxide, and the like. Only one kind of ceramic particles or two or more kinds of ceramic particles may be contained in the metal particle layer. In addition, the surface may be covered with a coating made of a resin, an oxide, or the like.

The size and shape of the ceramic particle are not particularly limited. For example, the size and shape of the ceramic particle may be the same as those described as a preferable aspect of the size and shape of the metal particle described above.

When the heat radiation material contains an additive, it is possible to impart a desired function to the heat radiation material or a material for forming the heat radiation material. Specific examples of the additive include a dispersant, a film-forming aid, a plasticizer, a pigment, a silane coupling agent, a viscosity modifier, and the like.

The shape of the heat radiation material is not particularly limited and can be selected depending on the use or the like. Examples thereof include a sheet shape, a film shape, a plate shape, and the like. Alternatively, the heat radiation material may be in a state of a layer formed by applying the material of the heat radiation material to a heat-generating element.

The thickness (the thickness of a portion at which the thickness is minimized in a case where the thickness is not constant) of the heat radiation material is not particularly limited. The thickness of the heat radiation material is preferably within a range of 1 μm to 500 μm and more preferably 10 μm to 200 μm. When the thickness of the heat radiation material is 500 μm or less, there is a tendency that the heat radiation material is less likely to be a heat-insulating layer and a favorable heat radiation property is maintained. When the thickness of the heat radiation material is 1 μm or more, there is a tendency that the function of the heat radiation material can be sufficiently obtained.

The wavelength range of electromagnetic waves that the heat radiation material absorbs or radiates is not particularly limited, but the absorptance or emissivity at each wavelength within 2 μm to 20 μm is preferably 0.8 or more and more preferably as close to 1.0 as possible from the viewpoint of the heat radiation property.

The absorptance of electromagnetic waves can be measured with a Fourier-transform infrared spectrometer. It is possible to consider that the absorptance and emissivity of electromagnetic waves are the same as each other according to the Kirchhoff s law.

The wavelength range of electromagnetic waves that the heat radiation material absorbs can be measured with a Fourier-transform infrared spectrometer. Specifically, the transmittance and the reflectance are measured at each wavelength, and the absorptance (emissivity) can be calculated from the following expression.

Absorptance(emissivity)=1−transmittance−reflectance

The uses of the heat radiation material are not particularly limited. For example, the heat radiation material may be installed in a place corresponding to a heat-generating element in an electronic device and used to dissipate heat generated from the heat-generating element. In addition, the heat radiation material may be used to transfer heat generated from a heat-generating element to a heat dissipater such as a metal plate or a heat sink.

### Heat Radiation Material (Second Embodiment)

A heat radiation material of the present embodiment is a heat radiation material in which metal particles and a resin are contained and the metal particles include metal particles arrayed along a surface direction.

The heat radiation material having the above-described configuration exhibits an excellent heat radiating effect in the case of being installed in a heat-generating element. The reason therefor is not clear but is considered as described below.

The heat radiation material having the above-described configuration contains metal particles arrayed along the surface direction (a direction perpendicular to the thickness direction). These metal particles form a layer having a fine uneven structure (metal particle layer) along the surface direction of the heat radiation material, and it is considered that, when heat is transferred from a heat-generating element, surface plasmon resonance occurs and the wavelength range of electromagnetic waves that are radiated changes. As a result, it is considered that, for example, the emissivity of electromagnetic waves in a wavelength range in which the resin that is contained in the radiation material does not absorb electromagnetic waves relatively increases, the accumulation of heat by the resin is suppressed, and the heat radiation property improves.

### Heat Radiation Material (Third Embodiment)

A heat radiation material of the present embodiment is a heat radiation material that contains metal particles and a resin and includes a layer having an uneven structure derived from the metal particles on the surface.

The heat radiation material having the above-described configuration exhibits an excellent heat radiating effect in the case of being installed in a heat-generating element. The reason therefor is not clear but is considered as described below.

The heat radiation material having the above-described configuration includes a layer having an uneven structure derived from the shapes of the metal particles on the surface (metal particle layer). When heat is transferred to this metal particle layer from a heat-generating element, it is considered that surface plasmon resonance occurs and the wavelength range of electromagnetic waves that are radiated changes. As a result, it is considered that, for example, the emissivity of electromagnetic waves in a wavelength range in which the resin that is contained in the radiation material does not absorb electromagnetic waves relatively increases, the accumulation of heat by the resin is suppressed, and the heat radiation property improves.

### Heat Radiation Material (Fourth Embodiment)

A heat radiation material of the present embodiment is a heat radiation material that contains metal particles and a resin and includes a region 1 and a region 2 that satisfy (A) and (B).

(A) an absorptance of electromagnetic wave at wavelength of 2 μm to 6 μm in the region 1>an absorptance of electromagnetic wave at wavelength of 2 μm to 6 μm in the region 2

(B) a metal particle occupancy rate in the region 1>a metal particle occupancy rate in the region 2

The heat radiation material having the above-described configuration exhibits an excellent heat radiating effect in the case of being installed in a heat-generating element. The reason therefor is not clear but is considered as described below.

Ordinarily, resins are less likely to absorb infrared light of short wavelengths and are likely to absorb infrared light of long wavelengths. Therefore, it is considered that, when the absorptance of electromagnetic waves within a wavelength range of 2 μm to 6 μm, in which resins are less likely to absorb electromagnetic waves, is increased (that is the emissivity is increased), the accumulation of heat by the resins is suppressed, and the heat radiation property improves.

The heat radiation material having the above-described configuration includes the region 1 in which the absorptance of electromagnetic waves in the wavelength range of 2 μm to 6 μm is higher than that of the region 2, whereby the above-described problem is solved.

Specific examples of the region 1 include a metal particle layer configured to contain a relatively larger number of metal particles to have a fine uneven structure formed of the metal particles and to generate a surface plasmon resonance effect. Specific examples of the region 2 include a resin layer containing a relatively larger amount of a resin. One of the region 1 and the region 2 may be disposed on a side on which the heat radiation material faces a heat-generating element, and the other may be disposed on a side opposite to the side on which the heat radiation material faces the heat-generating element.

The “metal particle occupancy rate” in the above-described configuration refers to the volume-based proportion of the metal particles in the region. The “absorptance of electromagnetic waves” can be measured in the same manner as the above-described absorptance of electromagnetic waves of the heat radiation material.

The specific configurations of the heat radiation materials of the respective embodiments described above, the details of the metal particles and the resins that are contained in the heat radiation materials, the preferable aspects, and the like are mutually applicable among the embodiments.

### Heat Radiation Material Production Method (First Embodiment)

A heat radiation material production method of the present embodiment includes a step of forming a layer (composition layer) of a composition containing metal particles and a resin and a step of settling the metal particles in the layer.

According to the above-described method, it is possible to produce the above-described heat radiation material.

In the method, the method for carrying out the step of forming a layer (composition layer) of a composition containing metal particles and a resin is not particularly limited. For example, the composition may be applied in a desired thickness onto a base material disposed such that the main surface becomes horizontal.

The base material to which the composition is applied may be removed after the production of the heat radiation material or before the use of the heat radiation material or may not be removed. Examples of the latter case include a case where the composition is directly applied to an object (heat-generating element) in which the heat radiation material is to be installed. The method for applying the composition is not particularly limited, and a well-known method such as brush coating, spray coating, roll coater coating, or immersion coating may be adopted. Electrostatic coating, curtain coating, electrodeposition coating, powder coating, or the like may also be adopted depending on the object to which the composition is to be applied.

In the method, the method for carrying out the step of settling the metal particles in the composition layer is not particularly limited. For example, the composition layer may be left to stand until the natural settling of the metal particles in the composition layer formed on the base material disposed such that the main surface becomes horizontal. From the viewpoint of accelerating the settling of the metal particles in the composition layer, when the density (mass per unit volume) of the metal particles is represented by A and the density of a component other than the metal particles is represented by B, A>B is preferably satisfied.

In the method, a treatment such as the drying, baking, or curing of the resin may be carried out after the step of settling the metal particles in the composition layer as necessary.

The kinds of the metal particles and the resin that are contained in the composition are not particularly limited. For example, the metal particles and the resin may be selected from the metal particles and the resin that are contained in the above-described heat radiation material. In addition, the other material described above that may be contained in the heat radiation material may be contained.

The composition may be in a state of a dispersion liquid containing a solvent (water-based emulsion or the like), varnish, or the like as necessary. Examples of the solvent that is contained in the composition include water and organic solvents, and the solvent is preferably selected in consideration of combination with other materials such as the metal particles and the resin that are contained in the composition. Examples of the organic solvents include organic solvents such as ketone solvents, alcohol solvents, and aromatic solvents. More specific examples thereof include methyl ethyl ketone, cyclohexene, ethylene glycol, propylene glycol, methyl alcohol, isopropyl alcohol, butanol, benzene, toluene, xylene, ethyl acetate, butyl acetate, and the like. One kind of solvent may be used or two or more kinds of solvents may be jointly used.

The detail and preferable aspect of a heat radiation material that is produced by the method may be the same as, for example, the detail and preferable aspect of the above-described heat radiation material.

### Heat Radiation Material Production Method (Second Embodiment)

A heat radiation material production method of the present embodiment includes a step of disposing metal particles on a flat surface and a step of forming a resin layer on the metal particles.

According to the above-described method, it is possible to produce the above-described heat radiation material.

In the method, the method for carrying out the step of disposing metal particles on a flat surface is not particularly limited. The metal particles may be disposed on the flat surface by laying the metal particles on a base material disposed such that the main surface becomes horizontal.

In the method, the method for carrying out the step of forming a resin layer on the metal particles is not particularly limited. For example, a resin shaped in a sheet shape may be disposed on the metal particles or a fluid resin may be applied onto the metal particles. At this time, the resin layer is preferably formed such that a part of the resin is present between the metal particles.

A treatment such as the drying, baking, or curing of the resin may be carried out after the step of forming the resin layer on the metal particles as necessary.

The kinds of the metal particles and the resin that are used in the method are not particularly limited. For example, the metal particles and the resin may be selected from the metal particles and the resin that are contained in the above-described heat radiation material. In addition, the other material described above that may be contained in the heat radiation material may be contained. Furthermore, the solvent that is used in the method of the first embodiment may also be contained.

The detail and preferable aspect of a heat radiation material that is produced by the method may be the same as, for example, the detail and preferable aspect of the above-described heat radiation material.

### Heat Radiation Material Production Method (Third Embodiment)

A heat radiation material production method of the present embodiment includes a step of preparing a resin layer and a step of disposing metal particles on the resin layer.

According to the above-described method, it is possible to produce the above-described heat radiation material.

In the method, the method for carrying out the step of preparing a resin layer is not particularly limited. For example, the resin layer may be formed by applying a fluid resin onto a base material or a resin shaped in a sheet shape may be used. In the case of using the resin shaped in a sheet shape, a laminating treatment may be carried out while keeping the resin and the metal particles in a vacuum in order to prevent the generation of a void between the metal particle and the resin.

In the method, the method for carrying out the step of disposing metal particles on the resin layer is not particularly limited. For example, the metal particles may be disposed on the resin surface by laying the metal particles on the resin layer in a state in which the resin layer is disposed such that the main surface becomes horizontal. At this time, the resin layer is preferably disposed such that the metal particles are inserted into the resin layer.

A treatment such as the drying, baking, or curing of the resin may be carried out after the step of disposing the metal particles on the resin layer as necessary.

The kinds of the metal particles and the resin that are used in the method are not particularly limited. For example, the metal particles and the resin may be selected from the metal particles and the resin that are contained in the above-described heat radiation material. In addition, the other material described above that may be contained in the heat radiation material may be contained. Furthermore, the solvent that is used in the method of the first embodiment may also be contained.

The detail and preferable aspect of a heat radiation material that is produced by the method may be the same as, for example, the detail and preferable aspect of the above-described heat radiation material.

<Composition>

A composition of the present embodiment is a composition that contains metal particles and a resin and is used to produce the above-described heat radiation material.

The detail and preferable aspect of the metal particles, the resin, and other components that are contained in the composition are the same as the detail and preferable aspect of the metal particles, the resin, and other components described in the sections of the heat radiation material and the production method thereof described above.

The ratio between the metal particles and the resin in the composition is not particularly limited. For example, the mass-based ratio (metal particles:resin) may be within a range of 0.1:99.9 to 99.9:0.1 or may be within a range of 1:99 to 50:50.

In the case of using the composition in the heat radiation material production method of the first embodiment, from the viewpoint of accelerating the settling of the metal particles in the composition, when the density (mass per unit volume) of the metal particles is represented by A and the density of a component other than the metal particles is represented by B, A>B is preferably satisfied.

<Heat-Generating Element>

A heat-generating element of the present embodiment includes the heat radiation material of the above-described embodiment.

The kind of the heat-generating element is not particularly limited. Examples thereof include an integrated circuit (CI) that is included in an electronic device, an electronic component such as a semiconductor element, a heat pipe, and the like.

An aspect of the heat radiation material being installed in the heat-generating element is not particularly limited. For example, a pressure-sensitive adhesive heat radiation material may be directly installed in the heat-generating element or the heat radiation material may be installed in the heat-generating element through an adhesive material or the like. In addition, a layer of the heat radiation material may be formed by applying the material of the heat radiation material to the heat-generating element.

When the heat radiation material is installed in the heat-generating element, the heat-generating element may be installed such that the side of the heat radiation material in which the metal particle layer is positioned comes into contact with the heat-generating element or the heat-generating element may be installed such that the side of the heat radiation material opposite to the side in which the metal particle layer is positioned comes into contact with the heat-generating element.

The heat-generating element may include a heat dissipater as necessary. In this case, the heat radiation material is preferably interposed between the main body of the heat-generating element and the heat dissipater. When the heat radiation material is interposed between the main body of the heat-generating element and the heat dissipater, an excellent heat radiation property is achieved. Examples of the heat dissipater include a plate made of metal such as aluminum, iron, or copper, a heat sink, and the like.

A portion of the main body in which the heat radiation material is installed may be a flat surface or may not be a flat surface. In a case where the portion of the main body in which the heat radiation material is installed is not a flat surface, the heat radiation material may be installed using a flexible heat radiation material.

### EXAMPLES

Hereinafter, the present disclosure will be described in more detail with reference to examples. However, the present disclosure is not limited to the contents described in the following examples.

### Example 1

An acrylic resin (99.13 vol %), copper particles (volume-average particle diameter: 2 μm) (0.87 vol %), and butyl acetate (30 mass % with respect to 100 mass % of the total of the two components described above) were put into a container and mixed using a hybrid mixer, thereby preparing a composition. This composition was applied by spraying to the entire surface of a 100 mm×100 mm aluminum plate having a thickness of 1 mm using a spray coating device to form a composition layer. This composition layer was naturally dried and cured by heating at 60° C. for 30 minutes, thereby producing a sample having a film thickness of 30 μm.

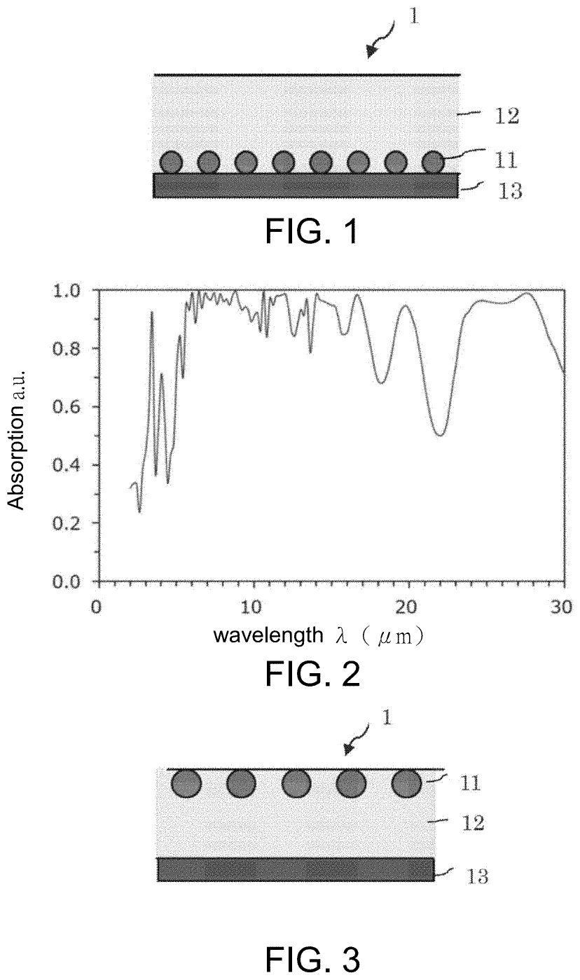

A cross-sectional schematic view of the produced sample is shown in FIG. 1. As shown in FIG. 1, a sample 1 contains copper particles 11 and a resin 12 and has a structure in which the copper particles 11 gather in an aluminum plate 13 side to form a metal particle layer. This is because the density of the copper particles that are contained in the composition is larger than the density of a component other than the copper particles in the composition and thus the copper particles settle in the composition layer.

As a result of measuring the distances of spaces between the copper particles that had settled from an image obtained with an optical microscope, the average distance (the arithmetic average value of distances measured for 100 arbitrarily selected particles) was 1 μm.

The thermal emissivity of the produced sample was measured (measurement wavelength range: 3 μm to 30 μm) at room temperature (25° C.) using an emissivity measuring instrument (manufactured by Kyoto Electronics Manufacturing Co., Ltd., D and S AERD). The emissivity of the sample of Example 1 was 0.9.

The absorption wavelength spectrum of the produced sample was investigated with a Fourier-transform infrared spectrometer. The obtained absorption wavelength spectrum is shown in FIG. 2. From the comparison with a sample of a sample (devoid of metal particles) of Comparative Example 1 described below, it is possible to confirm that the absorption efficiency increases particularly within a wavelength range of 10 μm or less.

### Example 2

An acrylic resin (96.5 vol %), copper particles (volume-average particle diameter: 8 μm) (3.5 vol %), and butyl acetate (30 mass % with respect to 100 mass % of the total of the two components described above) were put into a container and mixed using a hybrid mixer, thereby preparing a composition. This composition was applied onto a base material disposed such that the main surface became horizontal using an applicator (bar coater) to form a composition layer. This composition layer was naturally dried and cured by heating at 60° C. for 30 minutes, thereby producing a sample having a film thickness of 30 μm. Next, the sample was peeled off from the base material, and the surface opposite to the side from which the base material had been peeled off was attached to a 100 mm×100 mm aluminum plate having a thickness of 1 mm.

A cross-sectional schematic view of the produced sample is shown in FIG. 3. As shown in FIG. 3, a sample 1 contains copper particles 11 and a resin 12 and has a structure in which the copper particles 11 gather in a surface side opposite to an aluminum plate 13 to form a metal particle layer. This is because, between the sides of the sample with the copper particles settling into the base material side in the composition layer, a side opposite to the side to which the base material had adhered was attached to the aluminum plate. As a result of measurement in the same manner as in Example 1, the average distance between the settling copper particles was 4 μm.

The emissivity of the sample of Example 2 measured in the same manner as in Example 1 was 0.86.

An absorption wavelength spectrum obtained in the same manner as in Example 1 is shown in FIG. 4. From the comparison with the sample (devoid of metal particles) of Comparative Example 1 described below, it is possible to confirm that the absorption efficiency increases particularly within a wavelength range of 2 μm to 7 μm.

### Example 3

An acrylic resin (96.5 vol %), aluminum particles (volume-average particle diameter: 2 μm) (3.5 vol %), and butyl acetate (30 mass % with respect to 100 mass % of the total of the two components described above) were put into a container and mixed using a hybrid mixer, thereby preparing a composition. This composition was applied onto a base material disposed such that the main surface became horizontal using an applicator (bar coater) to form a composition layer. This composition layer was naturally dried and cured by heating at 60° C. for 30 minutes, thereby producing a sample having a film thickness of 30 μm. Next, the sample was peeled off from the base material, and the surface opposite to the side from which the base material had been peeled off was attached to a 100 mm×100 mm aluminum plate having a thickness of 1 mm.

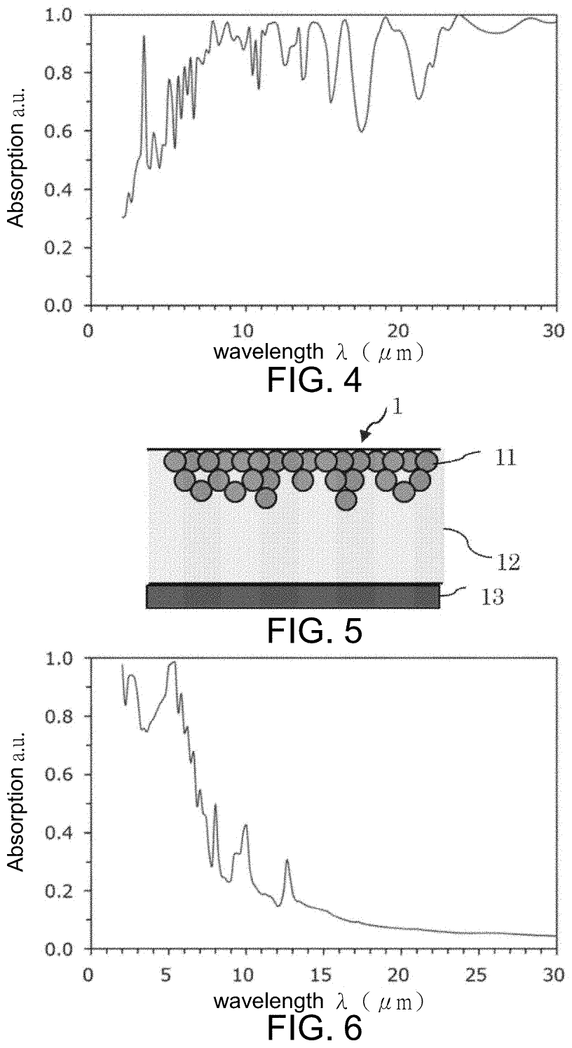

A cross-sectional schematic view of the produced sample is shown in FIG. 5. As shown in FIG. 5, a sample 1 contains aluminum particles 11 and a resin 12 and has a structure in which the aluminum particles 11 gather in a surface side opposite to an aluminum plate 13 to form a metal particle layer.

Since the amount of the metal particles in the composition was greater in the sample of Example 3 than in Example 1, the gaps between the metal particles are narrower and there are parts in which the metal particles overlap each other when seen in the thickness direction of the sample. FIG. 5 schematically shows a state in which the metal particles are arrayed in three layers, but the number of layers is not limited to three and may be two, and the metal particles may be arrayed in three or more layers.

An absorption wavelength spectrum obtained in the same manner as in Example 1 is shown in FIG. 6. From the comparison with the sample of Example 2, it is possible to confirm that the absorption efficiency within a wavelength range of 2 μm to 8 μm is higher than in Example 2 but the absorption efficiency within a wavelength range of 10 μm to 20 μm is lower than in Example 2. Therefore, compared with the sample (devoid of metal particles) of Comparative Example 1 described below, it is possible to selectively radiate infrared rays within a wavelength range in which infrared rays permeate the resin.

### Example 4

An acrylic resin (99.13 vol %), aluminum particles (volume-average particle diameter: 2 μm) having an acrylic resin coating (film thickness: 0.5 μm) provided as a spacer for adjusting the gaps between the particles to be constant therearound (0.87 vol %), and butyl acetate (30 mass % with respect to 100 mass % of the total of the two components described above) were put into a container and mixed using a hybrid mixer, thereby preparing a composition. This composition was applied by spraying to a 100 mm×100 mm aluminum plate having a thickness of 1 mm using a spray coating device to form a composition layer. This composition layer was naturally dried and cured by heating at 60° C. for 30 minutes, thereby producing a sample having a film thickness of 30 μm.

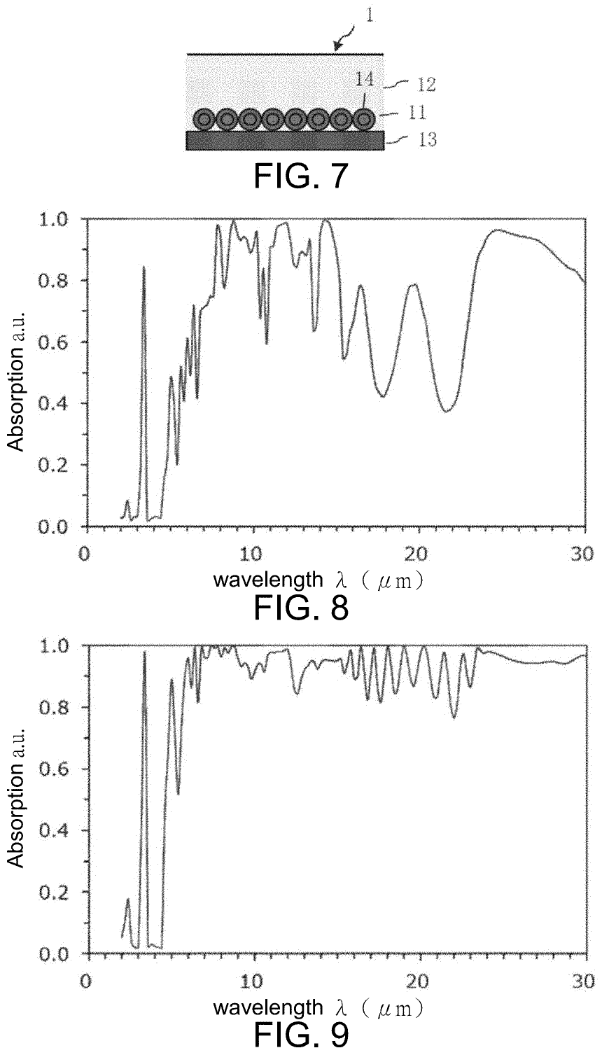

A cross-sectional schematic view of the produced sample is shown in FIG. 7. As shown in FIG. 7, a sample 1 contains aluminum particles 11 each having a resin film 14 therearound and a resin 12 and has a structure in which the aluminum particles 11 gather in an aluminum plate 13 side to form a metal particle layer. The average distance between the aluminum particles 11 (excluding the resin film parts) is adjusted to be 1 μm with the resin films 14.

The emissivity of the sample of Example 4 measured in the same manner as in Example 1 was 0.9.

The absorption wavelength spectrum of the sample of Example 4 becomes the same as the absorption wavelength spectrum shown in FIG. 2.

### Example 5

A sample having a film thickness of 30 μm was produced in the same manner as in Example 1 except that the copper particles were changed to the same amount of copper particles (volume-average particle diameter: 1 μm).

### Example 6

A sample having a film thickness of 100 μm was produced using the same composition as in Example 5.

### Comparative Example 1

Butyl acetate (30 mass %) was mixed with an acrylic resin (100 mass %), and a composition having an adjusted viscosity was prepared. This composition was applied by spraying to the entire surface of a 100 mm×100 mm aluminum plate having a thickness of 1 mm using a spray coating device to form a composition layer. This composition layer was naturally dried and cured by heating at 60° C. for 30 minutes, thereby producing a sample having a film thickness of 30 μm.

The emissivity of the sample of Comparative Example 1 measured in the same manner as in Example 1 was 0.7.

An absorption wavelength spectrum obtained in the same manner as in Example 1 is shown in FIG. 8.

### Comparative Example 2

The same composition as in Comparative Example 1 was applied by spraying to the entire surface of a 100 mm×100 mm aluminum plate having a thickness of 1 mm using a spray coating device to form a composition layer. This composition layer was naturally dried and cured by heating at 60° C. for 30 minutes, thereby producing a sample having a film thickness of 100 μm.

The emissivity of the sample of Comparative Example 2 measured in the same manner as in Example 1 was 0.9.

An absorption wavelength spectrum obtained in the same manner as in Example 1 is shown in FIG. 9. From the comparison with the sample of Comparative Example 1, it is found that an increase in the thickness of the sample increased the absorption efficiency within a wavelength range of 8 μm or more and made the emissivity higher than in Comparative Example 1.

### Comparative Example 3

A commercially available heat-radiating paint containing an acrylic resin (95 vol %) and silicon dioxide particles (volume-average particle diameter: 2 μm) (5 vol %) was applied by spraying to a 100 mm×100 mm aluminum plate having a thickness of 1 mm using a spray coating device to form a composition layer. This composition layer was naturally dried and cured by heating at 60° C. for 30 minutes, thereby producing a sample having a film thickness of 30 μm.

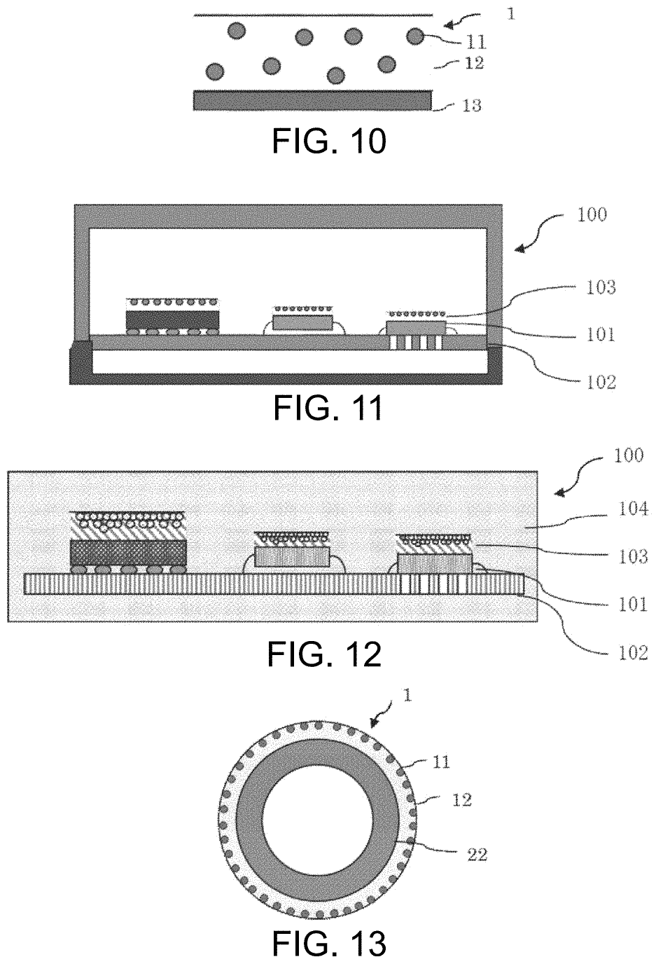

A cross-sectional schematic view of the produced sample is shown in FIG. 10. As shown in FIG. 10, a sample 1 contains silicon dioxide particles 11 and a resin 12 and has a structure in which the silicon dioxide particles 11 do not gather in an aluminum plate 13 side but are dispersed in the resin 12.

The emissivity of the sample of Comparative Example 3 measured in the same manner as in Example 1 was 0.81.

The heat radiation properties were evaluated by the following method using the compositions prepared in the examples and the comparative examples. The results are shown in Table 1.

A commercially available planar heat-generating element (polyimide heater) is sandwiched by aluminum plates (50 mm×80 mm, thickness: 2 mm). K thermocouples are attached to the surfaces of the aluminum plates with solder for aluminum, respectively. The composition is fully applied to both surfaces of one aluminum plate and naturally dried to produce a sample having a thickness of 30 μm. The aluminum plate on which the sample has been formed is placed still at the center of a constant temperature tank set to 25° C., and the temperature change on the surface of the aluminum plate is measured. At this time, the output of the heater is set such that the surface temperature of the aluminum plate with no sample formed thereon reaches 100° C. Since the heater generates a constant amount of heat, the higher the heat radiating effect, the lower the surface temperature of the aluminum plate. That is, it can be said that the lower the surface temperature of the aluminum plate, the higher the heat radiating effect. The measured surface temperatures (peak temperatures) of the aluminum plates are shown in Table 1.

TABLE 1

| | Comparative | Comparative | Comparative | | | | | | |
|---|---|---|---|---|---|---|---|---|---|
| | Example 1 | Example 2 | Example 3 | Example 1 | Example 2 | Example 3 | Example 4 | Example 5 | Example 6 |
| Film thickness | 30 | 100 | 30 | 30 | 30 | 30 | 30 | 30 | 100 |
| (μm) | | | | | | | | | |
| Peak temperature | 85 | 80 | 78 | 70 | 75 | 69 | 71 | 64 | 66 |
| (° C.) | | | | | | | | | |

As shown in Table 1, compared with the surface temperature (100° C.) of the aluminum plate in which the sample was not installed, the surface temperatures of the aluminum plates lowered to 85° C. and 80° C., respectively, in Comparative Example 1 and Comparative Example 2 in which the sample only containing the resin was installed, but the temperature lowering effects thereof were small compared with the examples. This is considered to be because the samples included no metal particle layer and thus the heat radiating effects by heat radiation heat transfer were small compared with the examples.

In Comparative Example 3 in which the sample having a structure in which the silicon dioxide particles were dispersed in the resin was installed, the surface temperature of the aluminum plate lowered to 78° C., but the temperature lowering effect thereof was small compared with the examples. This is considered to be because the silicon dioxide particles were dispersed in the resin and thus it was not possible to sufficiently obtain a heat radiation property-amplifying effect by surface plasmon resonance.

### Example 7

The sample produced in Example 2 was installed in an electronic component (heat-generating element) of an electronic device as shown in FIG. 11, and the temperature lowering effect was investigated.

An electronic device 100 shown in FIG. 11 includes an electronic component 101 and a circuit board 102 in which the electronic component 101 is mounted. A sample 103 produced in Example 2 is peeled off from the base material, and the surface opposite to the side from which the base material has been peeled off is installed on the upper part of the electronic component 101. As a result of operating this electronic device, the temperature of the electronic component 101 lowered from 125° C. (without the sample) to 95° C.

### Example 8

The sample produced in Example 3 was installed in an electronic component (heat-generating element) of an electronic device as shown in FIG. 12, and the temperature lowering effect was investigated.

An electronic device 100 shown in FIG. 12 includes an electronic component 101 and a circuit board 102 in which the electronic component 101 is mounted. Furthermore, the periphery of the electronic component 101 is sealed with a resin 104. A sample 103 produced in Example 3 is peeled off from the base material, and the surface opposite to the side from which the base material has been peeled off is installed on the upper part of the electronic component 101. As a result of operating this electronic device, the temperature of the electronic component 101 lowered from 155° C. (without the sample) to 115° C.

### Example 9

The sample produced in Example 1 was installed in a heat pipe (heat-generating element) as shown in FIG. 13, and the temperature lowering effect was investigated.

A heat pipe 22 shown in FIG. 13 is a stainless steel pipe (diameter: 32 mm), and a sample 1 installed on the periphery of the heat pipe contains copper particles 11 and a resin 12 and has a structure in which the copper particles 11 gather in a side opposite to the side in contact with the heat pipe 22 to form a metal particle layer. After water (90° C.) was caused to flow through the inside of the heat pipe, the surface temperature lowered from 85° C. (without the sample) to 68° C.

All of the documents, patent applications, and technical standards described in the present specification are incorporated into the present specification to substantially the same extent as a case where each of the documents, patent applications, and technical standards is specifically and separately incorporated by reference.

1. A heat radiation material comprising:
metal particles; and
a resin,
wherein the heat radiation material has a structure in which the metal particles are localized in at least one surface side.

2. The heat radiation material according to claim 1,
wherein a region in which the metal particles are present at a relatively high density is present in the at least one surface side.

3. The heat radiation material according to claim 2,
wherein the region is present in a surface side that faces a heat-generating element.

4. The heat radiation material according to claim 2,
wherein the region is present in a surface side opposite to a surface that faces the heat-generating element.

5. The heat radiation material according to claim 2,
wherein a thickness of the region is within a range of 0.1 μm to 100 μm.

6. The heat radiation material according to claim 2,
wherein a proportion of a thickness of the region in a thickness of the entire heat radiation material is within a range of 0.02% to 99%.

7. A heat radiation material comprising:
metal particles; and
a resin,
wherein the metal particles comprise metal particles arrayed along a surface direction.

8. A heat radiation material comprising:
metal particles; and
a resin,
wherein a layer having an uneven structure derived from the metal particles on a surface is provided.

9. A heat radiation material comprising:
metal particles; and
a resin,
wherein a region 1 and a region 2 that satisfy (A) and (B) are provided,
(A) an absorptance of electromagnetic wave at wavelength of 2 μm to 6 μm in the region 1>an absorptance of electromagnetic wave at wavelength of 2 μm to 6 μm in the region 2, and
(B) a metal particle occupancy rate in the region 1>a metal particle occupancy rate in the region 2.

10. A method for producing a heat radiation material comprising:
a step of forming a layer of a composition containing metal particles and a resin; and
a step of settling the metal particles in the layer.

11. A method for producing a heat radiation material comprising:
a step of disposing metal particles on a flat surface; and
a step of forming a resin layer on the metal particles.

12. A method for producing a heat radiation material comprising:
a step of preparing a resin layer; and
a step of disposing metal particles on the resin layer.

13. A composition comprising:
metal particles; and
a resin,
wherein the composition is used to produce the heat radiation material according to claim 1.

14. A heat-generating element comprising:
the heat radiation material according to claim 1.

15. The heat radiation material according to claim 3,
wherein the region is present in a surface side opposite to a surface that faces the heat-generating element.

16. The heat radiation material according to claim 3,
wherein a thickness of the region is within a range of 0.1 μm to 100 μm.

17. The heat radiation material according to claim 4,
wherein a thickness of the region is within a range of 0.1 μm to 100 μm.

18. The heat radiation material according to claim 3,
wherein a proportion of a thickness of the region in a thickness of the entire heat radiation material is within a range of 0.02% to 99%.

19. The heat radiation material according to claim 4,
wherein a proportion of a thickness of the region in a thickness of the entire heat radiation material is within a range of 0.02% to 99%.

20. The heat radiation material according to claim 5,
wherein a proportion of a thickness of the region in a thickness of the entire heat radiation material is within a range of 0.02% to 99%.
